(19) United States
(12) Patent Application Publication
(10) Pub. No.: US 2023/0313039 A1
(43) Pub. Date: Oct. 5, 2023

(54) ETCHING GAS COMPOSITION, SUBSTRATE PROCESSING APPARATUS, AND PATTERN FORMING METHOD USING THE SAME

(71) Applicant: SEMES CO., LTD., Chungcheongnam-do (KR)

(72) Inventors: Kyungseok MIN, Suwon-si (KR); Hyunjong SHIM, Seongnam-si (KR); Sangmin MUN, Cheonan-si (KR); Sunjoo PARK, Seoul-si (KR); Hwan JUNG, Hwaseong-si (KR); Nayeon LEE, Cheonan-si (KR)

(21) Appl. No.: 18/189,427

(22) Filed: Mar. 24, 2023

(30) Foreign Application Priority Data
Apr. 1, 2022 (KR) 10-2022-0041226

(51) Int. Cl. C09K 13/00; H01L 21/311

(52) U.S. Cl. CPC C09K 13/00; H01L 21/31116; H01L 21/31144

(57) ABSTRACT

An etching gas composition includes at least two types of organofluorine compounds of carbon number C3 or carbon number C4, wherein the at least two types of organofluorine compounds are isomeric to each other.

### CROSS-REFERENCE TO RELATED APPLICATION

This application is based on and claims priority under 35 U.S.C. § 119 to Korean Patent Application No. 10-2022-0041226, filed on Apr. 1, 2022, in the Korean Intellectual Property Office, the disclosure of which is incorporated by reference herein in its entirety.

### BACKGROUND

### 1. Field

The disclosure relates to an etching gas composition, a substrate processing apparatus, and a pattern forming method using the same. More particularly, the disclosure relates to an etching gas composition, a substrate processing apparatus, and a pattern forming method using the same, which may reduce a pattern hole distortion according to an etching process and may improve a pattern profile.

### 2. Description of the Related Art

With the development of the electronic industry, the integration degree of semiconductor devices has increased and miniaturization of pattern sizes has been continuously required. Accordingly, there is a need for an etching gas composition that may provide an excellent etch selectivity and may improve a pattern profile.

### SUMMARY

Provided is an etching gas composition that may provide an excellent etch selectivity and may improve a pattern profile.

Provided is a substrate processing apparatus using an etching gas composition that may provide an excellent etch selectivity and may improve a pattern profile.

Provided is a pattern forming method capable of providing an excellent etch selectivity and improving a pattern profile.

Additional aspects will be set forth in part in the description which follows and, in part, will be apparent from the description, or may be learned by practice of the presented embodiments of the disclosure.

According to an aspect of the disclosure, an etching gas composition includes at least two types of organofluorine compounds of carbon number C3 or carbon number C4, wherein the at least two types of organofluorine compounds are isomeric to each other.

In an embodiment, the at least two organofluorine compounds may have a chemical formula of C₃H₂F₆.

In an embodiment, the at least two types of organofluorine compounds may be selected respectively from among 1,1,1,3,3,3 -hexafluoropropane, 1,1,1,2,3,3-hexafluoropropane, or 1,1,2,2,3,3-hexafluoropropane.

In an embodiment, the at least two types of organofluorine compounds may include a first organofluorine compound and a second organofluorine compound, and the first organofluorine compound may be 1,1,1,2,3,3-hexafluoropropane and the second organofluorine compound may be selected from among 1,1,1,3,3,3-hexafluoropropane or 1,1,2,2,3,3 -hexafluoropropane.

In an embodiment, in the organofluorine compound, a molar ratio of the first organofluorine compound may be selected in a range of about 70 mol % to about 80 mol % and a molar ratio of the second organofluorine compound may be selected in a range of about 20 mol % to about 30 mol %.

In an embodiment, the at least two types of organofluorine compounds may include a first organofluorine compound and a second organofluorine compound, and the first organofluorine compound may be 1,1,1,3,3,3-hexafluoropropane and the second organofluorine compound may be 1,1,2,2,3,3 -hexafluoropropane.

In an embodiment, in the organofluorine compound, a molar ratio of the first organofluorine compound may be selected in a range of about 40 mol % to about 60 mol % and a molar ratio of the second organofluorine compound may be selected in a range of about 40 mol % to about 60 mol %.

In an embodiment, the at least two organofluorine compounds may have a chemical formula of C₄H₂F₆.

In an embodiment, the at least two organofluorine compounds may be selected respectively from among hexafluoroisobutene, (2Z)-1,1,1,4,4,4-hexafluoro-2-butene, 2,3,3,4,4,4-hexafluoro-1-butene, (2Z)- 1,1,1,2,4,4-hexafluoro-2-butene, (2Z)-1,1,2,3 ,4,4-hexafluoro-2-butene, 1,1,2,3,4,4-hexafluoro-2-butene, (3R, 4S)-1,1,2,2,3,4-hexafluorocyclobutane, or 1,1,2,2,3,3 -hexafluorocyclobutane.

In an embodiment, the at least two types of organofluorine compounds may include a third organofluorine compound and a fourth organofluorine compound, wherein the third organofluorine compound may be (2Z)-1,1,1,4,4,4-hexafluoro-2-butene and the fourth organofluorine compound may be selected from among hexafluoroisobutene or (3R, 4S)-1,1,2,2,3,4-hexafluorocyclobutane.

In an embodiment, in the organofluorine compound, a molar ratio of the third organofluorine compound may be selected in a range of about 70 mol % to about 80 mol % and a molar ratio of the fourth organofluorine compound may be selected in a range of about 20 mol % to about 30 mol %.

In an embodiment, the at least two organofluorine compounds may include a third organofluorine compound and a fourth organofluorine compound, wherein the third organofluorine compound may be hexafluoroisobutene and the fourth organofluorine compound may be (3R, 4S)-1,1,2,2,3,4-hexafluorocyclobutane.

In an embodiment, in the organofluorine compound, a molar ratio of the third organofluorine compound may be selected in a range of about 40 mol % to about 60 mol % and a molar ratio of the fourth organofluorine compound may be selected in a range of about 40 mol % to about 60 mol %.

In an embodiment, the etching gas composition may further include an inert gas and a reactive gas, wherein the inert gas may be selected from among argon (Ar), helium (He), neon (Ne), or a mixture thereof and the reactive gas may be oxygen (O₂).

According to another aspect of the disclosure, a substrate processing apparatus includes a chamber including a processing space in which a substrate is processed, a gas supply device configured to supply an etching gas composition to the processing space, and a substrate support device arranged in the processing space and configured to support the substrate, wherein the etching gas composition includes at least two types of organofluorine compounds of carbon number C3 or carbon number C4, and the at least two types of organofluorine compounds are isomeric to each other.

In an embodiment, the substrate processing apparatus may further include a shower head arranged over the substrate and including a plurality of gas supply holes.

According to another aspect of the disclosure, a pattern forming method includes forming an etch target layer over a substrate, forming an etch mask over the etch target layer, etching the etch target layer through the etch mask by using plasma obtained from an etching gas composition, and removing the etch mask, wherein the etching gas composition includes at least two types of organofluorine compounds of carbon number C3 or carbon number C4, and the at least two types of organofluorine compounds are isomeric to each other.

In an embodiment, the etch mask may include at least one of a photoresist (PR), a spin-on hardmask (SOH), or an amorphous carbon layer (ACL).

In an embodiment, the etching target layer may include at least one of silicon nitride and silicon oxide.

In an embodiment, a plasma source for obtaining the plasma may include any one of high-frequency inductively coupled plasma (ICP) or capacitively coupled plasma (CCP).

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a substrate processing apparatus using an etching gas composition according to an embodiment;

FIG. 2 is a flowchart illustrating a pattern forming method according to an embodiment; and

FIGS. 3A to 3F are cross-sectional views respectively illustrating operations of a semiconductor device manufacturing method according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments of the inventive concept will be described in detail with reference to the accompanying drawings. Herein, like reference numerals will denote like elements, and redundant descriptions thereof will be omitted for conciseness.

An etching gas composition according to an embodiment may include at least two types of organofluorine compounds of carbon number C3 or carbon number C4, wherein the at least two types of organofluorine compounds may be isomeric to each other.

In an embodiment, the at least two types of organofluorine compounds may have a chemical formula of C₃H₂F₆.

In an embodiment, the at least two types of organofluorine compounds may be selected respectively from among 1,1,1,3,3,3 -hexafluoropropane, 1,1,1,2,3,3 -hexafluoropropane, or 1,1,2,2,3,3 -hexafluoropropane.

In an embodiment, the at least two types of organofluorine compounds may include a first organofluorine compound and a second organofluorine compound, and the first organofluorine compound may be 1,1,1,2,3,3-hexafluoropropane and the second organofluorine compound may be selected from among 1,1,1,3,3,3-hexafluoropropane or 1,1,2,2,3,3-hexafluoropropane. For example, the first organofluorine compound may be 1,1,1,2,3,3-hexafluoropropane and the second organofluorine compound may be 1,1,1,3,3,3-hexafluoropropane.

In an embodiment, in the organofluorine compound, a molar ratio of the first organofluorine compound may be selected in a range of about 60 mol % to about 90 mol % and a molar ratio of the second organofluorine compound may be selected in a range of about 15 mol % to about 40 mol %. In an embodiment, in the organofluorine compound, a molar ratio of the first organofluorine compound may be selected in a range of about 65 mol % to about 85 mol % and a molar ratio of the second organofluorine compound may be selected in a range of about 20 mol % to about 30 mol %. In an embodiment, in the organofluorine compound, a molar ratio of the first organofluorine compound may be selected in a range of about 70 mol % to about 80 mol % and a molar ratio of the second organofluorine compound may be selected in a range of about 20 mol % to about 30 mol %. For example, when the first organofluorine compound is 1,1,1,2,3,3-hexafluoropropane and the second organofluorine compound is 1,1,1,3,3,3-hexafluoropropane, a molar ratio of the first organofluorine compound in the organofluorine compound may be 75 mol % and a molar ratio of the second organofluorine compound may be 25 mol %.

When a mixing ratio of the first organofluorine compound and the second fluorine compound is the same as above, a desired etch rate and etch selectivity may be obtained. Particularly, for example, in a case where the first organofluorine compound is 1,1,1,2,3,3-hexafluoropropane and the second organofluorine compound is 1,1,1,3,3,3-hexafluoropropane, when the content of the first organofluorine compound is too low, the etch selectivity thereof may degrade, and when the content of the first organofluorine compound is too high, the etch rate thereof may degrade.

In an embodiment, the at least two types of organofluorine compounds may include a first organofluorine compound and a second organofluorine compound, and the first organofluorine compound may be 1,1,1,3,3,3-hexafluoropropane and the second organofluorine compound may be 1,1,2,2,3,3-hexafluoropropane.

In an embodiment, in the organofluorine compound, a molar ratio of the first organofluorine compound may be selected in a range of about 30 mol % to about 70 mol % and a molar ratio of the second organofluorine compound may be selected in a range of about 30 mol % to about 70 mol %. In an embodiment, in the organofluorine compound, a molar ratio of the first organofluorine compound may be selected in a range of about 40 mol % to about 60 mol % and a molar ratio of the second organofluorine compound may be selected in a range of about 40 mol % to about 60 mol %. For example, in the organofluorine compound, a molar ratio of the first organofluorine compound may be 50 mol % and a molar ratio of the second organo fluorine compound may be 50 mol %.

When a mixing ratio of the first organofluorine compound and the second fluorine compound is the same as above, a desired etch rate and etch selectivity may be obtained. Particularly, when the content of the first organofluorine compound is too low, the etch rate may degrade, and when the content of the first organofluorine compound is too high, the etch selectivity may degrade.

In an embodiment, the at least two types of organofluorine compounds may have a chemical formula of C₄H₂F₆.

In an embodiment, the at least two organofluorine compounds may be selected respectively from among hexafluoroisobutene, (2Z)- 1,1,1,4,4,4-hexafluoro-2-butene, (3R, 4S)-1,1,2,2,3,4-hexafluorocyclobutane, 2,3,3,4,4,4-hexafluoro- 1-butene, 1,1,2,2,3,3 -hexafluorocyclobutane, (2Z)-1,1,1,2,4,4-hexafluoro-2-butene, (2Z)- 1,1,2,3,4,4-hexafluoro-2-butene, or 1,1,2,3,4,4-hexafluoro-2-butene.

In an embodiment, the at least two types of organofluorine compounds may include a third organofluorine compound and a fourth organofluorine compound, wherein the third organofluorine compound may be (2Z)-1,1,1,4,4,4-hexafluoro-2-butene and the fourth organofluorine compound may be selected from among hexafluoroisobutene or (3R, 4S)-1,1,2,2,3,4-hexafluorocyclobutane. For example, the third organofluorine compound may be (2Z)-1,1,1,4,4,4-hexafluoro-2-butene and the fourth organofluorine compound may be (3R, 4S)-1,1,2,2,3,4-hexafluorocyclobutane.

In an embodiment, in the organofluorine compound, a molar ratio of the third organofluorine compound may be selected in a range of about 60 mol % to about 90 mol % and a molar ratio of the fourth organofluorine compound may be selected in a range of about 15 mol % to about 40 mol %. In an embodiment, in the organofluorine compound, a molar ratio of the third organofluorine compound may be selected in a range of about 65 mol % to about 85 mol % and a molar ratio of the fourth organofluorine compound may be selected in a range of about 20 mol % to about 30 mol %. In an embodiment, in the organofluorine compound, a molar ratio of the third organofluorine compound may be selected in a range of about 70 mol % to about 80 mol % and a molar ratio of the fourth organofluorine compound may be selected in a range of about 20 mol % to about 30 mol %. For example, when the third organofluorine compound is (2Z)-1,1,1,4,4,4-hexafluoro-2-butene and the second organofluorine compound is hexafluoroisobutene, a molar ratio of the third organofluorine compound in the organofluorine compound may be 75 mol % and a molar ratio of the fourth organofluorine compound may be 25 mol %.

When a mixing ratio of the third organofluorine compound and the fourth fluorine compound is the same as above, a desired etch rate and etch selectivity may be obtained. Particularly, for example, in a case where the third organofluorine compound is (2Z)-1,1,1,4,4,4-hexafluoro-2-butene and the fourth organofluorine compound is hexafluoroisobutene, when the content of the third organofluorine compound is too low, the etch selectivity thereof may degrade, and when the content of the third organofluorine compound is too high, the etch rate thereof may degrade.

In an embodiment, the at least two organofluorine compounds may include a third organofluorine compound and a fourth organofluorine compound, wherein the third organofluorine compound may be hexafluoroisobutene and the fourth organofluorine compound may be (3R, 4S)-1,1,2,2,3,4-hexafluorocyclobutane.

In an embodiment, in the organofluorine compound, a molar ratio of the third organofluorine compound may be selected in a range of about 30 mol % to about 70 mol % and a molar ratio of the fourth organofluorine compound may be selected in a range of about 30 mol % to about 70 mol %. In an embodiment, in the organofluorine compound, a molar ratio of the third organofluorine compound may be selected in a range of about 40 mol % to about 60 mol % and a molar ratio of the fourth organofluorine compound may be selected in a range of about 40 mol % to about 60 mol %. For example, in the organofluorine compound, a molar ratio of the third organofluorine compound may be 50 mol % and a molar ratio of the fourth organofluorine compound may be 50 mol %.

When a mixing ratio of the third organofluorine compound and the fourth fluorine compound is the same as above, a desired etch rate and etch selectivity may be obtained. Particularly, when the content of the third organofluorine compound is too low, the etch rate may degrade, and when the content of the third organofluorine compound is too high, the etch selectivity may degrade.

In a semiconductor device manufacturing process, an etching gas composition may include various types of fluorine compounds, inert gases, oxygen, and/or the like. In this case, the content of oxygen included in the etching gas composition may be adjusted according to the aspect ratio of a pattern to be formed or the type of a fluorine compound included in the etching gas composition. For example, the etching gas composition including a fluorine compound that is more likely to be deposited during an etching process may include a higher content of oxygen (more oxygen) than the etching gas composition including a fluorine compound that is less likely to be deposited during an etching process. When the etching gas composition includes a higher content of oxygen, the etch rate of the etching gas composition may increase but a problem such as degradation of the selectivity of the etching gas composition with respect to an etch mask or degradation of the profile of a pattern formed by using the etching gas composition may occur. On the other hand, the etching gas composition according to an embodiment may include at least two types of organofluorine compounds of carbon number C3 or carbon number C4 that are isomeric to each other, and may be used to form patterns with various aspect ratios by adjusting the ratio of the organofluorine compounds without adjusting the content of oxygen. Particularly, a pattern with a high aspect ratio may be formed by adjusting the ratio of the organofluorine compounds without increasing the content of oxygen included in the etching gas composition. Accordingly, the profile of a pattern formed by using the etching gas composition may be improved while maintaining a relatively high selectivity of the etching gas composition.

In an embodiment, the etching gas composition may further include an inert gas. The inert gas may include, for example, any one of helium (He), neon (Ne), argon (Ar), xenon (Xe), or a mixture thereof but is not limited thereto.

In an embodiment, the etching gas composition may further include a reactive gas. The reactive gas may include, for example, any one of oxygen (O₂), carbon monoxide (CO), carbon dioxide (CO₂), nitrogen monoxide (NO), nitrogen dioxide (NO₂), nitrous oxide (N₂O), hydrogen (H₂), ammonia (NH₃), hydrogen fluoride (HF), sulfur dioxide (SO₂), carbon disulfide (CS₂), carbonyl sulfide (COS), CF₃I, C₂F₃I, C₂F₅I, or a mixture thereof but is not limited thereto.

The etching gas composition described above may provide an excellent etch selectivity of a silicon compound (e.g., silicon oxide and/or silicon nitride) with respect to an amorphous carbon layer (ACL). Particularly, because the etch selectivity of SiO₂/ACL and Si₃N₄/ACL is excellent, it may be excellently used for channel hole etching and cell metal contact (CMC).

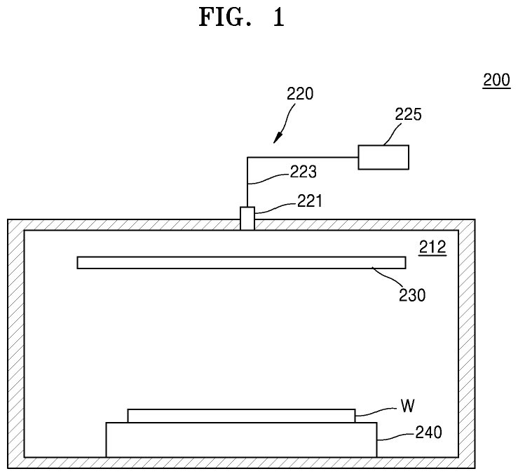

FIG. 1 is a cross-sectional view illustrating a substrate processing apparatus 200 using an etching gas composition according to an embodiment.

Referring to FIG. 1, a substrate processing apparatus 200 may include a chamber 210, a gas supply device 220, a shower head 230, and a substrate support device 240.

The chamber 210 may have a barrel shape including a space therein. The chamber 210 may include a processing space 212 therein. The shower head 230 and the substrate support device 240 may be located in the processing space 212. The chamber 210 may have a square shape in a front section but is not limited thereto.

The gas supply device 220 may be located over the chamber 210. The gas supply device 220 may supply an etching gas composition according to an embodiment to the processing space 212. The etching gas composition may be brought into a plasma state by a plasma source (not illustrated).

The gas supply device 220 may include a gas supply nozzle 221, a gas supply line 223, and a gas supply source 225. The gas supply nozzle 221 may be located at a center portion of the upper surface of the chamber 210. The gas supply nozzle 221 may vertically pass through the upper surface of the chamber 210. An injection hole may be formed at the lower surface of the gas supply nozzle 221. The gas supply nozzle 221 may supply the etching gas composition to the processing space 212 through the injection hole. The gas supply line 223 may connect the gas supply nozzle 221 with the gas supply source 225. The gas supply line 223 may supply the etching gas composition supplied from the gas supply source 225 to the gas supply nozzle 221. Although not illustrated in FIG. 1, a valve (not illustrated) may be arranged on the gas supply line 223. The valve may be used to control the supply of the etching gas composition to the gas supply nozzle 221. For example, when the valve is opened, the etching gas composition may be supplied to the gas supply nozzle 221, and when the valve is closed, the etching gas composition may not be supplied to the gas supply nozzle 221. The valve may include, for example, a plurality of valves but is not limited thereto. The gas supply source 225 may supply the etching gas composition to the gas supply nozzle 221 through the gas supply line 223. As an etching process is performed by using the etching gas composition, the critical dimension (CD) of a pattern line formed by the etching process may be reduced and thus the profile of a pattern may be improved.

The plasma source may bring the etching gas composition supplied to the processing space 212 into a plasma state. In an embodiment, the plasma source may be inductively coupled plasma (ICP) or capacitively coupled plasma (CCP). However, the plasma source is not limited thereto and may be, for example, a reactive ion etching (RIE) equipment, a magnetically enhanced reactive ion etching (MERIE) equipment, a transformer coupled plasma (TCP) equipment, a hollow anode type plasma equipment, a helical resonator plasma equipment, an electron cyclotron resonance (ECR) plasma equipment, or the like.

The shower head 230 may be arranged in the processing space 212. The shower head 230 may be located to be spaced apart from the upper surface of the chamber 210 by a certain distance in a direction toward the substrate support device 240. The shower head 230 may be located over the substrate support device 240 and a substrate W. The shower head 230 may have, for example, a plate shape but is not limited thereto. The cross-sectional area of the shower head 230 may be greater than the cross-sectional area of the substrate support device 240 but is not limited thereto. In an embodiment, the lower surface of the shower head 230 may be anodized to prevent the occurrence of an arc due to plasma. The shower head 230 may include a plurality of gas supply holes (not illustrated). The gas supply holes may vertically pass through the upper and lower surfaces of the shower head 230. The etching gas composition supplied through the gas supply holes by the gas supply device 220 may be supplied under the shower head 230.

The substrate support device 240 may be arranged on the lower surface of the chamber 210 in the processing space 212. The substrate support device 240 may be, for example, an electrostatic chuck for adsorbing the substrate W by using an electrostatic force but is not limited thereto. The substrate support device 240 may support the substrate W. The substrate support device 240 may have, for example, a disk shape but is not limited thereto. The cross-sectional area of the substrate support device 240 may be greater than the cross-sectional area of the substrate W but is not limited thereto.

Although not illustrated in FIG. 1, the substrate processing apparatus 200 may include a controller (not illustrated). The controller may control an operation of the substrate processing apparatus 200. For example, the controller may be configured to transmit/receive electrical signals to/from the gas supply device 220 and accordingly may be configured to control an operation of the gas supply device 220.

The controller may be implemented as hardware, firmware, software, or any combination thereof. For example, the controller may be a computing device such as a workstation computer, a desktop computer, a laptop computer, or a tablet computer. For example, the controller may include a memory device such as a read only memory (ROM) or a random access memory (RAM), and a processor configured to perform certain operations and algorithms, such as a microprocessor, a central processing unit (CPU), or a graphics processing unit (GPU). Also, the controller may include a receiver and a transmitter for receiving and transmitting electrical signals.

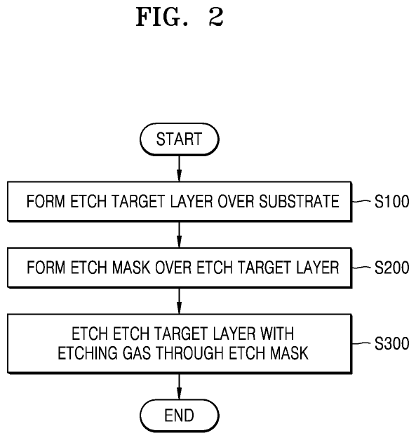

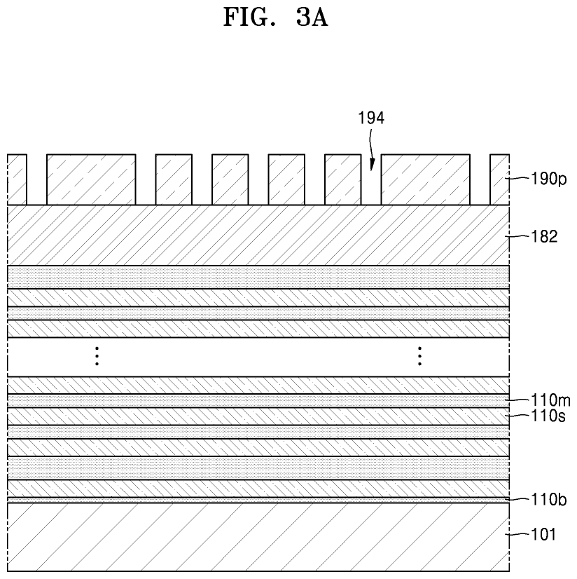

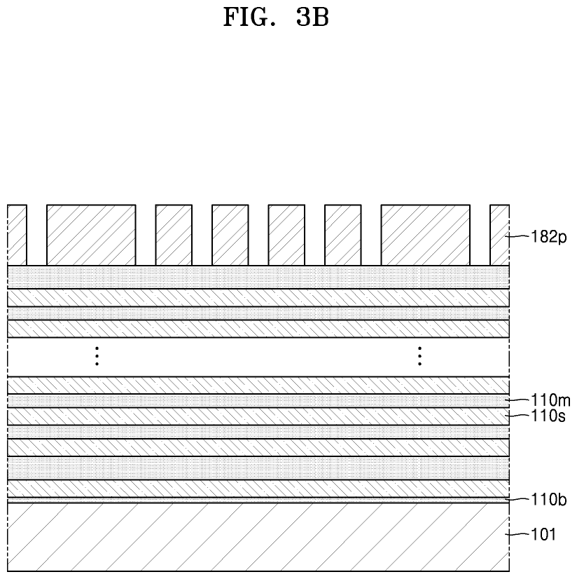

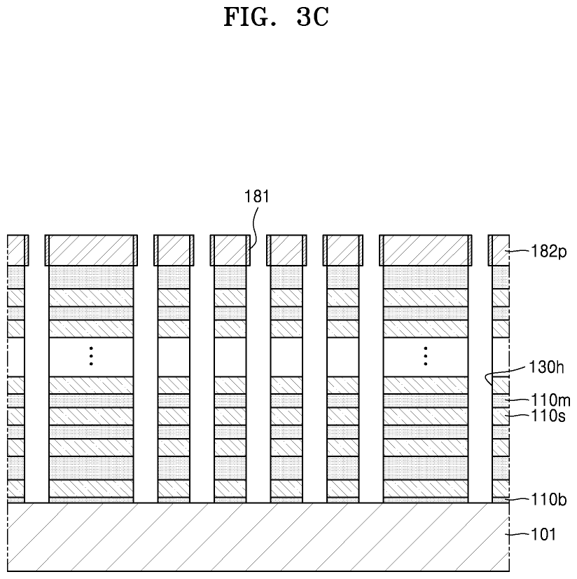

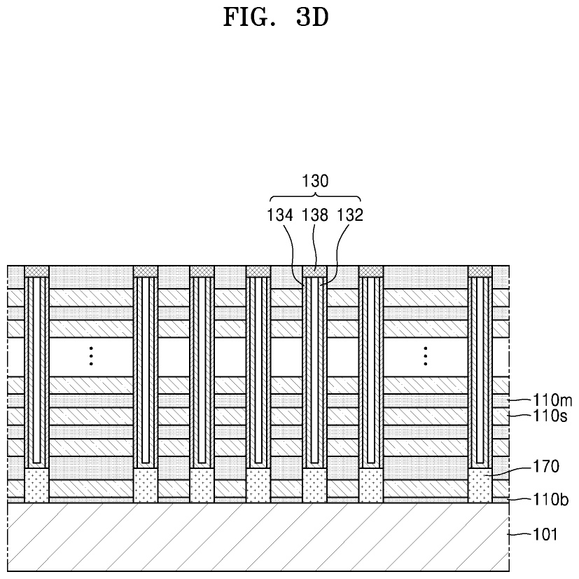

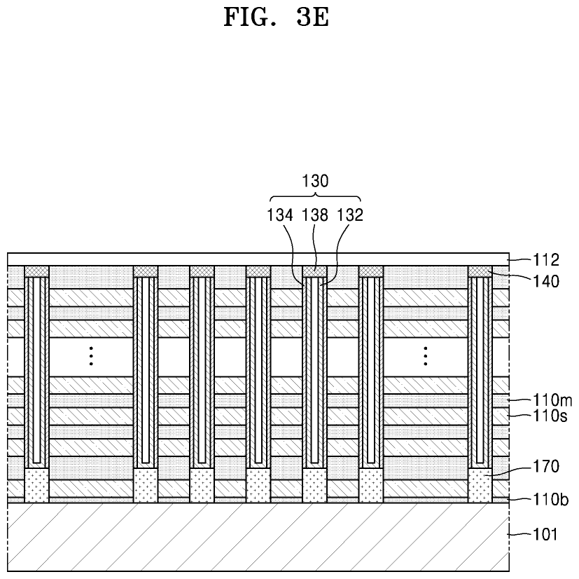

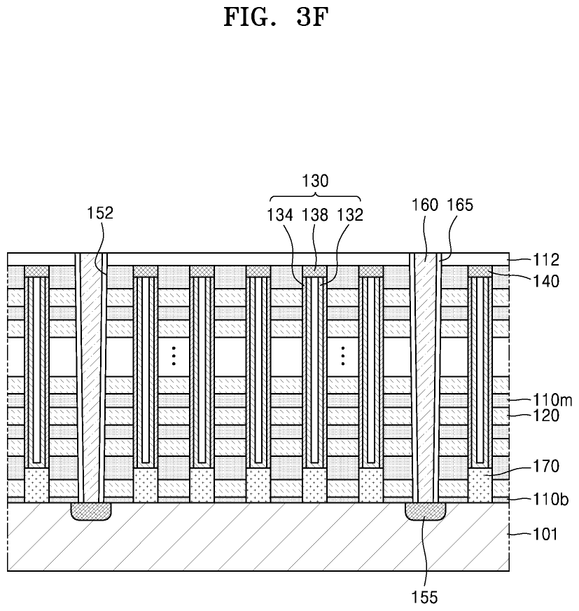

FIG. 2 is a flowchart illustrating a pattern forming method according to an embodiment. FIGS. 3A to 3F are cross-sectional views respectively illustrating operations of a semiconductor device manufacturing method according to an embodiment.

Referring to FIGS. 2 and 3A, an etch target layer (i.e., a layer to be etched) may be formed by alternately and repeatedly stacking a sacrificial layer 110s and an insulating layer 110m as an etch target layer over a substrate 101 (S100).

The substrate 101 may include a group IV semiconductor such as silicon (Si) or germanium (Ge), a group IV-IV compound semiconductor such as silicon-germanium (SiGe) or silicon carbide (SiC), or a III-V group compound semiconductor such as gallium arsenide (GaAs), indium arsenide (InAs), or indium phosphide (InP). The substrate 101 may be provided as a bulk wafer or as an epitaxial layer. In another embodiment, the substrate 101 may include a silicon-on-insulator (SOI) substrate or a germanium-on-insulator (GeOI) substrate. In an embodiment, the substrate 101 may include a first conductivity type (e.g., p-type) well.

The sacrificial layer 110s may be formed of a material having an etch selectivity with respect to the insulating layer 110m. For example, the sacrificial layer 110s may be selected to be removed at a higher etch selectivity than the insulating layer 110m in an etching process using an etchant. For example, the insulating layer 110m may be a silicon oxide layer or a silicon nitride layer, and the sacrificial layer 110s may be selected from among a silicon oxide layer, a silicon nitride layer, silicon carbide, polysilicon, and silicon germanium and may be selected to have a high etch selectivity with respect to the silicon insulating layer 110m. For example, when the sacrificial layer 110s includes silicon oxide, the insulating layer 110m may include silicon nitride. As another example, when the sacrificial layer 110s includes silicon nitride, the insulating layer 110m may include silicon oxide. As another example, when the sacrificial layer 110s includes undoped polysilicon, the insulating layer 110m may include silicon nitride or silicon oxide.

The sacrificial layer 110s and the insulating layer 110m may be formed by chemical vapor deposition (CVD), physical vapor deposition (PVD), or atomic layer deposition (ALD).

A thermal oxide layer 110b may be provided between the substrate 101 and the sacrificial layer 110s formed closest to the substrate 101. The thermal oxide layer 110b may have a smaller thickness than the insulating layer 110m.

A hard mask material layer 182 and a photoresist mask pattern 190p may be sequentially formed over the sacrificial layer 110s and the insulating layer 110m that have been alternately stacked.

The hard mask material layer 182 may include a carbon-based material having a suitable etch selectivity with respect to an amorphous carbon layer (ACL), a spin-on hardmask (SOH), the sacrificial layer 110s, and the insulating layer 110m.

The photoresist mask pattern 190p may include a resist for extreme ultraviolet (EUV) (13.5 nm), a resist for KrF excimer laser (248 nm), a resist for ArF excimer laser (193 nm), or a resist for F2 excimer laser (157 nm). The photoresist mask pattern 190p may include a plurality of hole patterns 194 corresponding to channel holes 130h (see FIG. 3C) to be formed later in a memory cell area.

Referring to FIGS. 2 and 3B, a hard mask pattern 182p may be formed by etching the hard mask material layer 182 (see FIG. 3A) by using the photoresist mask pattern 190p (see FIG. 3A) as an etch mask (S200). The etching may be dry anisotropic etching.

A portion where the hard mask material layer 182 has been exposed by the hole patterns 194 of the photoresist mask pattern 190p may be removed by the etching, to expose the upper surface of the insulating layer 110m.

Because the hard mask material layer 182 is protected by the photoresist mask pattern 190p in a portion where the photoresist mask pattern 190p exists, it may remain without being etched.

FIGS. 3A and 3B illustrate that the hard mask material layer 182 and the photoresist mask pattern 190p are sequentially formed over the sacrificial layer 110s and the insulating layer 110m that have been alternately stacked, and the hard mask pattern 182p is formed by etching the hard mask material layer 182 by using the photoresist mask pattern 190p as an etch mask; however, the disclosure is not limited thereto. For example, only one of the hard mask pattern 182p or the photoresist mask pattern 190p may be formed over the sacrificial layers 110 and the insulating layer 110m that have been alternately stacked, and one of the hard mask pattern 182p and the photoresist mask pattern 190p may be directly used as an etch mask to etch the sacrificial layer 110s and the insulating layer 110m.

Referring to FIGS. 2 and 3C, channel holes 130h passing through the sacrificial layer 110s and the insulating layer 110m may be formed by using the hard mask pattern 182p as an etch mask (S300).

In order to form the channel holes 130h passing through the sacrificial layer 110s and the insulating layer 110m, power may be supplied and an electrical bias may be applied while supplying an etching gas composition and oxygen. The etching gas composition may be converted into a plasma state by the supplied power, and anisotropic etching may be performed by the electrical bias. The etching gas composition may be the etching gas composition according to the embodiment described above. As an etching process is performed by using the etching gas composition, the CD of a pattern line may be reduced and thus the profile of a pattern may be improved.

In an embodiment, an etching equipment using plasma may be an inductively coupled plasma (ICP) equipment or a capacitively coupled plasma (CCP) equipment. However, the etching equipment using plasma is not limited thereto and may be, for example, a reactive ion etching (RIE) equipment, a magnetically enhanced reactive ion etching (MERIE) equipment, a transformer coupled plasma (TCP) equipment, a hollow anode type plasma equipment, a helical resonator plasma equipment, an electron cyclotron resonance (ECR) plasma equipment, or the like.

During performance of the anisotropic etching by the etching gas composition in the plasma state, a passivation layer 181 may be formed the side surface of the hard mask pattern 182p. The passivation layer 181 may include a fluorocarbon-based polymer including C—C, C—F, and C—H bonds. The passivation layer 181 may increase the selectivity of the etch target layer and improve the LER and LWR of the etch mask, such as ACL, SOH, and PR. Accordingly, a high aspect ratio contact (HARC) with a high aspect ratio may be formed with an excellent quality with reduced bowing or tapering.

In an embodiment, the anisotropic etching may be performed at a temperature of about 250 K to about 420 K, about 260 K to about 400 K, about 270 K to about 380 K, about 280 K to about 360 K, or about 290 K to about 340 K.

Referring to FIGS. 2 and 3D, a semiconductor pattern 170 may be formed to a certain height in the channel hole 130h.

The semiconductor pattern 170 may be formed by selective epitaxial growth (SEG) using the exposed upper surface of the substrate 101 as a seed. Accordingly, the semiconductor pattern 170 may be formed to include monocrystalline silicon according to the material of the substrate 101 and may be doped with dopants as necessary. In an embodiment, the semiconductor pattern 170 may be formed by forming an amorphous silicon layer to fill the channel hole 130h to a certain height and then performing laser epitaxial growth (LEG) or solid phase epitaxy (SPE) on the amorphous silicon layer.

Thereafter, a vertical channel structure 130 may be formed in the channel hole 130h.

The vertical channel structure 130 may include an information storage pattern 134, a vertical channel pattern 132, and a filling insulating pattern 138. The information storage pattern 134 may be arranged between the sacrificial layer 110s and the vertical channel pattern 132. In embodiments, the information storage pattern 134 may be provided in the form of a tube including opening portions at upper and lower portions thereof. The information storage pattern 134 may be provided such that the upper surface of the semiconductor pattern 170 may be exposed. In embodiments, the information storage pattern 134 may include a layer capable of storing data by using a Fowler-Nordheim tunneling effect. In embodiments, the information storage pattern 134 may include a thin film capable of storing data based on a different operation principle.

In embodiments, the information storage pattern 134 may be formed of a plurality of thin films. For example, the information storage pattern 134 may include a plurality of thin films such as a blocking insulating layer, a charge storage layer, and a tunnel insulating layer.

The vertical channel pattern 132 may be formed to conformally cover the side surface of the information storage pattern 134 and the exposed upper surface of the semiconductor pattern 170. The vertical channel pattern 132 may be directly connected to the semiconductor pattern 170. The vertical channel pattern 132 may include a semiconductor material (e.g., a polycrystalline silicon layer, a monocrystalline silicon layer, or an amorphous silicon layer). In embodiments, the vertical channel pattern 132 may be formed by ALD or CVD.

The filling insulating pattern 138 may be formed to fill the remaining portion of the channel hole 130h not filled by the information storage pattern 134 and the vertical channel pattern 132. The filling insulating pattern 138 may include a silicon oxide layer or a silicon nitride layer. In embodiments, before the forming of the filling insulating pattern 138, a hydrogen annealing process may be further performed to cure crystal defects that may exist in the vertical channel pattern 132.

Referring to FIGS. 2 and 3E, a conductive pad 140 may be formed on each of the vertical channel structures 130.

In embodiments, in order to form the conductive pad 140, an upper portion of the vertical channel structure 130 may be recessed and a conductive material may be formed to fill the recessed portion. In embodiments, the conductive pad 140 may be formed by implanting impurities into the upper portion of the vertical channel structure 130.

Thereafter, a cap insulating layer 112 may be formed over the conductive pad 140 and the uppermost insulating layer 110m. The cap insulating layer 112 may be a silicon oxide layer, a silicon nitride layer, or the like and may be formed by CVD or ALD.

Referring to FIGS. 2 and 3F, a word line cut trench 152 extending to the upper surface of the substrate 101 may be formed in a portion of the memory cell area, and a common source line 155 may be formed by implanting impurities into the substrate 101 through the word line cut trench 152. The impurities may have a conductivity type opposite to the conductivity type of the well or the substrate 101 of a portion where the common source line 155 is formed.

Thereafter, the sacrificial layer 110s may be replaced with a gate electrode through the word line cut trench 152.

For this purpose, the sacrificial layer 110s may be first removed through the word line cut trench 152. As described above with reference to FIGS. 2 and 3A, because the sacrificial layer 110s is selected to have a high etch selectivity with respect to the insulating layer 110m, the sacrificial layer 110s may be selectively removed by selecting a suitable etchant.

Thereafter, a barrier layer (not illustrated) and a gate electrode material layer may be sequentially formed to fill a space with the sacrificial layer 110s removed therefrom. The barrier layer may be formed of a material such as TiN or TaN by CVD or ALD to have a thickness of about 30 angstroms to about 150 angstroms.

The gate electrode material layer may be formed of metal such as tungsten (W), copper (Cu), aluminum (Al), platinum (Pt), titanium (Ti), or tantalum (Ta), metal silicide, conductive metal nitride such as titanium nitride (TiN) or tantalum nitride (TaN), polysilicon, or amorphous silicon and may be doped with dopants as necessary. The gate electrode material layer may be formed to fill a remaining space remaining after the forming of the barrier layer. Thereafter, the gate electrode material layer in the word line cut trench may be patterned to form a gate electrode 120.

Then, an isolation insulating layer 165 and a conductive layer 160 may be sequentially formed in the word line cut trench 152.

The isolation insulating layer 165 may include any one of a silicon nitride layer, a silicon oxide layer, or a silicon oxynitride layer and may be formed by CVD or ALD. The conductive layer 160 may include metal such as tungsten or copper and may be formed by CVD or ALD.

Hereinafter, the configuration and effect of the disclosure will be described in more detail with reference to particular experimental examples and comparative examples; however, these experimental examples are merely for a clearer understanding of the disclosure and are not intended to limit the scope of the disclosure.

### EMBODIMENTS 1 TO 6 AND COMPARATIVE EXAMPLES 1 TO 9

By using an etching gas composition having a composition of Table 1 below, an etch rate for each etch target layer and a diameter difference of a channel hole formed in the etch target layer are measured under the condition of Table 1, and the results thereof are summarized in Table 2. The diameter difference of the channel hole formed in the etch target layer is measured through the difference between the maximum diameter and the minimum diameter of each of the channel holes formed by using the etching gas composition having the composition of Table 1 below.

TABLE 1

| | 1,1,1,3,3,3- | 1,1,1,2,3,3- | 1,1,2,2,3,3- | | | | | |
|---|---|---|---|---|---|---|---|---|
| | hexafluoropropane | hexafluoropropane | hexafluoropropane | Ar | O₂ | Power | T | Time |
| | Sccm | | | | | W | K | Sec |
| Embodiment 1 | 25 | 25 | 0 | 150 | 20 | 400 | 293 | 60 |
| Embodiment 2 | 30 | 20 | 0 | 150 | 20 | 400 | 293 | 60 |
| Embodiment 3 | 25 | 0 | 25 | 150 | 20 | 400 | 293 | 60 |
| Embodiment 4 | 30 | 0 | 20 | 150 | 20 | 400 | 293 | 60 |
| Embodiment 5 | 0 | 25 | 25 | 150 | 20 | 400 | 293 | 60 |
| Embodiment 6 | 0 | 20 | 30 | 150 | 20 | 400 | 293 | 60 |
| Comparative | 50 | 0 | 0 | 150 | 20 | 400 | 293 | 60 |
| Example 1 | | | | | | | | |
| Comparative | 50 | 0 | 0 | 150 | 30 | 400 | 293 | 60 |
| Example 2 | | | | | | | | |
| Comparative | 50 | 0 | 0 | 150 | 40 | 400 | 293 | 60 |
| Example 3 | | | | | | | | |
| Comparative | 0 | 50 | 0 | 150 | 20 | 400 | 293 | 60 |
| Example 4 | | | | | | | | |
| Comparative | 0 | 50 | 0 | 150 | 30 | 400 | 293 | 60 |
| Example 5 | | | | | | | | |
| Comparative | 0 | 50 | 0 | 150 | 40 | 400 | 293 | 60 |
| Example 6 | | | | | | | | |
| Comparative | 0 | 0 | 50 | 150 | 20 | 400 | 293 | 60 |
| Example 7 | | | | | | | | |
| Comparative | 0 | 0 | 50 | 150 | 30 | 400 | 293 | 60 |
| Example 8 | | | | | | | | |
| Comparative | 0 | 0 | 50 | 150 | 40 | 400 | 293 | 60 |
| Example 9 | | | | | | | | |

TABLE 2

| | | | Selectivity | | Contact Hole |
|---|---|---|---|---|---|
| | SiO₂ | Si₃N₄ | SiO₂/ | Si₃N₄/ | Diameter Difference |
| | nm/min | | ACL | ACL | Nm |
| Embodiment | 163.09 | 148.17 | 8.3 | 7.51 | 55 |
| 1 | | | | | |
| Embodiment | 170.38 | 150.29 | 7.54 | 6.88 | 58.31 |
| 2 | | | | | |
| Embodiment | 125.14 | 113.67 | 9.29 | 8.37 | 27.33 |
| 3 | | | | | |
| Embodiment | 130.43 | 116.45 | 8.75 | 7.87 | 29.47 |
| 4 | | | | | |
| Embodiment | 112.32 | 102.14 | 12.95 | 11.82 | 25 |
| 5 | | | | | |
| Embodiment | 110.28 | 100.27 | 14.27 | 12.75 | 23.5 |
| 6 | | | | | |
| Comparative | 165.48 | 150.31 | 5.15 | 4.82 | 66.87 |
| Example 1 | | | | | |
| Comparative | 171.39 | 155.87 | 4.01 | 3.92 | 75.98 |
| Example 2 | | | | | |
| Comparative | 180.43 | 162.09 | 2.87 | 2.75 | 88.13 |
| Example 3 | | | | | |
| Comparative | 145.83 | 132.08 | 9.03 | 8.14 | 28.33 |
| Example 4 | | | | | |
| Comparative | 151.98 | 136.23 | 7.67 | 6.82 | 34.87 |
| Example 5 | | | | | |
| Comparative | 160.54 | 142.76 | 6.35 | 5.51 | 41.29 |
| Example 6 | | | | | |
| Comparative | 99.87 | 91.12 | 16.12 | 14.52 | 22.71 |
| Example 7 | | | | | |
| Comparative | 105.98 | 96.67 | 13.47 | 12.29 | 33.56 |
| Example 8 | | | | | |
| Comparative | 111.27 | 101.86 | 12.01 | 10.74 | 42.01 |
| Example 9 | | | | | |

As shown in Table 2, in the case of Comparative Examples 1 to 9, it may be seen that, as the amount of oxygen supplied increases, the etch rate increases but simultaneously the selectivity degrades rapidly.

On the other hand, in the case of Embodiments 1 to 6, as described above, it may be seen that the etch rate and the etch selectivity may be adjusted by adjusting the content of each of the organofluorine compounds without adjusting the amount of oxygen supplied, and the selectivity may be maintained relatively high while the etch rate increases according to a change in the content of each of the organofluorine compounds included in the etching gas composition.

Thus, it may be seen that it may be advantageous to use the etching gas composition of Embodiments 1 to 6 in etching the etch target layer with a high aspect ratio.

### EMBODIMENTS 7 TO 12 AND COMPARATIVE EXAMPLES 10 TO 18

By using an etching gas composition having a composition of Table 3 below, an etch rate for each etch target layer and a diameter difference of a channel hole formed in the etch target layer are measured under the condition of Table 3, and the results thereof are summarized in Table 4. The diameter difference of the channel hole formed in the etch target layer is measured in the same way as described above.

TABLE 3

| | | (2Z)-1,1,1,4,4,4- | (3R, 4S)-1,1,2,2,3,4- | | | | | |
|---|---|---|---|---|---|---|---|---|
| | hexafluoroisobutene | hexafluoro-2-butene | hexafluorocyclobutane | Ar | O₂ | Power | T | Time |
| | Sccm | | | | | W | K | Sec |
| Embodiment 7 | 25 | 25 | 0 | 150 | 80 | 400 | 293 | 60 |
| Embodiment 8 | 30 | 20 | 0 | 150 | 80 | 400 | 293 | 60 |
| Embodiment 9 | 25 | 0 | 25 | 150 | 80 | 400 | 293 | 60 |
| Embodiment 10 | 30 | 0 | 20 | 150 | 80 | 400 | 293 | 60 |
| Embodiment 11 | 0 | 25 | 25 | 150 | 80 | 400 | 293 | 60 |
| Embodiment 12 | 0 | 20 | 30 | 150 | 80 | 400 | 293 | 60 |
| Comparative | 50 | 0 | 0 | 150 | 70 | 400 | 293 | 60 |
| Example 10 | | | | | | | | |
| Comparative | 50 | 0 | 0 | 150 | 75 | 400 | 293 | 60 |
| Example 11 | | | | | | | | |
| Comparative | 50 | 0 | 0 | 150 | 80 | 400 | 293 | 60 |
| Example 12 | | | | | | | | |
| Comparative | 0 | 50 | 0 | 150 | 70 | 400 | 293 | 60 |
| Example 13 | | | | | | | | |
| Comparative | 0 | 50 | 0 | 150 | 75 | 400 | 293 | 60 |
| Example 14 | | | | | | | | |
| Comparative | 0 | 50 | 0 | 150 | 80 | 400 | 293 | 60 |
| Example 15 | | | | | | | | |
| Comparative | 0 | 0 | 50 | 150 | 70 | 400 | 293 | 60 |
| Example 16 | | | | | | | | |
| Comparative | 0 | 0 | 50 | 150 | 75 | 400 | 293 | 60 |
| Example 17 | | | | | | | | |
| Comparative | 0 | 0 | 50 | 150 | 80 | 400 | 293 | 60 |
| Example 18 | | | | | | | | |

TABLE 4

| | | | selectivity | | Contact Hole |
|---|---|---|---|---|---|
| | SiO₂ | Si₃N₄ | SiO₂/ | Si₃N₄/ | Diameter Difference |
| | nm/min | | ACL | ACL | Nm |
| Embodiment | 231.67 | 208.1 | 10.12 | 9.28 | 71.09 |
| 7 | | | | | |
| Embodiment | 242.13 | 218.52 | 9.37 | 8.65 | 80.37 |
| 8 | | | | | |
| Embodiment | 190.2 | 172.12 | 11.56 | 10.47 | 62.12 |
| 9 | | | | | |
| Embodiment | 197.09 | 179.18 | 11.08 | 10.05 | 70.19 |
| 10 | | | | | |
| Embodiment | 186.98 | 168.21 | 12.11 | 10.86 | 67.85 |
| 11 | | | | | |
| Embodiment | 179.03 | 161.59 | 12.86 | 11.57 | 75.31 |
| 12 | | | | | |
| Comparative | 207.66 | 189.17 | 13.28 | 9.92 | 80.78 |
| Example 10 | | | | | |
| Comparative | 226.17 | 209.15 | 11.41 | 9.33 | 88.1 |
| Example 11 | | | | | |
| Comparative | 239.33 | 213.78 | 9.61 | 8.65 | 98.49 |
| Example 12 | | | | | |
| Comparative | 177.76 | 161.39 | 15.89 | 14.29 | 70.56 |
| Example 13 | | | | | |
| Comparative | 194.08 | 176.08 | 13.48 | 12.17 | 78.09 |
| Example 14 | | | | | |
| Comparative | 214.39 | 201.98 | 11.27 | 10.31 | 86.67 |
| Example 15 | | | | | |
| Comparative | 157.2 | 143.07 | 17.02 | 15.47 | 59.87 |
| Example 16 | | | | | |
| Comparative | 170.28 | 163.54 | 14.56 | 13.1 | 66.54 |
| Example 17 | | | | | |
| Comparative | 186.93 | 175.11 | 12.2 | 11.07 | 73.33 |
| Example 18 | | | | | |

As shown in Table 4, in the case of Comparative Examples 10 to 18, it may be seen that, as the amount of oxygen supplied increases, the etch rate increases but simultaneously the selectivity degrades rapidly.

On the other hand, in the case of Embodiments 7 to 12, as described above, it may be seen that the etch rate and the etch selectivity may be adjusted by adjusting the content of each of the organofluorine compounds without adjusting the amount of oxygen supplied, and the selectivity may be maintained relatively high while the etch rate increases according to a change in the content of each of the organofluorine compounds included in the etching gas composition.

Thus, it may be seen that it may be advantageous to use the etching gas composition of Embodiments 7 to 12 in etching the etch target layer with a high aspect ratio.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. An etching gas composition comprising at least two types of organofluorine compounds of carbon number C3 or carbon number C4, wherein the at least two types of organofluorine compounds are isomeric to each other.

2. The etching gas composition of claim 1, wherein the at least two organofluorine compounds have a chemical formula of C₃H₂F₆.

3. The etching gas composition of claim 1, wherein the at least two types of organofluorine compounds are respectively selected from among 1,1,1,3,3,3-hexafluoropropane, 1,1,1,2,3,3-hexafluoropropane, or 1,1,2,2,3,3-hexafluoropropane.

4. The etching gas composition of claim 3, wherein the at least two types of organofluorine compounds comprise a first organofluorine compound and a second organofluorine compound, and
the first organofluorine compound is 1,1,1,2,3,3-hexafluoropropane and the second organofluorine compound is selected from among 1,1,1,3,3,3-hexafluoropropane or 1,1,2,2,3,3-hexafluoropropane.

5. The etching gas composition of claim 4, wherein in the organofluorine compound, a mole ratio of the first organofluorine compound is selected in a range of about 70 mol % to about 80 mol % and a mole ratio of the second organofluorine compound is selected in a range of about 20 mol % to about 30 mol %.

6. The etching gas composition of claim 3, wherein the at least two types of organofluorine compounds comprise a first organofluorine compound and a second organofluorine compound, and
the first organofluorine compound is 1,1,1,3,3,3-hexafluoropropane and the second organofluorine compound is 1,1,2,2,3,3-hexafluoropropane.

7. The etching gas composition of claim 6, wherein in the organofluorine compound, a molar ratio of the first organofluorine compound is selected in a range of about 40 mol % to about 60 mol % and a molar ratio of the second organofluorine compound is selected in a range of about 40 mol % to about 60 mol %.

8. The etching gas composition of claim 1, wherein the at least two organofluorine compounds have a chemical formula of C₄H₂F₆.

9. The etching gas composition of claim 1, wherein the at least two organofluorine compounds are respectively selected from among hexafluoroisobutene, (2Z)-1,1,1,4,4,4-hexafluoro-2-butene, 2,3,3,4,4,4-hexafluoro-1-butene, (2Z)-1,1,1,2,4,4-hexafluoro-2-butene, (2Z)-1,1,2,3,4,4-hexafluoro-2-butene, 1,1,2,3,4,4-hexafluoro-2-butene, (3R, 4S)-1,1,2,2,3,4-hexafluorocyclobutane, or 1,1,2,2,3,3-hexafluorocyclobutane.

10. The etching gas composition of claim 9, wherein
the at least two types of organofluorine compounds comprise a third organofluorine compound and a fourth organofluorine compound, and
the third organofluorine compound is (2Z)-1,1,1,4,4,4-hexafluoro-2-butene and the fourth organofluorine compound is selected from among hexafluoroisobutene or (3R, 4S)-1,1,2,2,3,4-hexafluorocyclobutane.

11. The etching gas composition of claim 10, wherein in the organofluorine compound, a molar ratio of the third organofluorine compound is selected in a range of about 70 mol % to about 80 mol % and a molar ratio of the fourth organofluorine compound is selected in a range of about 20 mol % to about 30 mol %.

12. The etching gas composition of claim 9, wherein the at least two organofluorine compounds comprise a third organofluorine compound and a fourth organofluorine compound, and
the third organofluorine compound is hexafluoroisobutene and the fourth organofluorine compound is (3R, 4S)-1,1,2,2,3,4-hexafluorocyclobutane.

13. The etching gas composition of claim 12, wherein in the organofluorine compound, a molar ratio of the third organofluorine compound is selected in a range of about 40 mol% to about 60 mol % and a molar ratio of the fourth organofluorine compound is selected in a range of about 40 mol % to about 60 mol %.

14. The etching gas composition of claim 1, further comprising an inert gas and a reactive gas,
wherein the inert gas is selected from among argon (Ar), helium (He), neon (Ne), or a mixture thereof and the reactive gas is oxygen (O₂).

15. A substrate processing apparatus comprising:
a chamber including a processing space in which a substrate is processed;
a gas supply device configured to supply an etching gas composition to the processing space; and
a substrate support device arranged in the processing space and configured to support the substrate,
wherein the etching gas composition comprises at least two types of organofluorine compounds of carbon number C3 or carbon number C4, and the at least two types of organofluorine compounds are isomeric to each other.

16. The substrate processing apparatus of claim 15, further comprising a shower head arranged over the substrate and including a plurality of gas supply holes.

17. A pattern forming method comprising:
forming an etch target layer over a substrate;
forming an etch mask over the etch target layer;
etching the etch target layer through the etch mask by using plasma obtained from an etching gas composition; and
removing the etch mask,
wherein the etching gas composition comprises at least two types of organofluorine compounds of carbon number C3 or carbon number C4, and the at least two types of organofluorine compounds are isomeric to each other.

18. The pattern forming method of claim 17, wherein the etch mask comprises at least one of a photoresist (PR), a spin-on hardmask (SOH), or an amorphous carbon layer (ACL).

19. The pattern forming method of claim 17, wherein the etching target layer comprises at least one of silicon nitride or silicon oxide.

20. The pattern forming method of claim 17, wherein a plasma source for obtaining the plasma comprises any one of high-frequency inductively coupled plasma (ICP) or capacitively coupled plasma (CCP).
